(19) United States
(12) Patent Application Publication
(10) Pub. No.: US 2026/0290695 A1
(43) Pub. Date: Sep. 24, 2026

(54) STACKED CAPACITOR PACKAGING STRUCTURE AND METHOD OF MANUFACTURING THE SAME, AND AN ELECTRONIC DEVICE

(71) Applicant: AiPAQ Technology CO., LTD, Miaoli County (TW)

(72) Inventors: KUO-FANG KU, Miaoli County (TW); WEN-CHING LEE, Miaoli County (TW); MING-GOO CHIEN, Miaoli County (TW)

(21) Appl. No.: 19/193,137

(22) Filed: Apr. 29, 2025

(30) Foreign Application Priority Data
Mar. 20, 2025 (TW) 114110429

(51) Int. Cl. H01G 4/224; H01G 4/008; H01G 4/232; H01G 4/30; H05K 1/11; H05K 1/18

(52) U.S. Cl. CPC H01G 4/224; H01G 4/008; H01G 4/232; H01G 4/30; H05K 1/111; H05K 1/181; H05K 2201/10015

(57) ABSTRACT

A stacked capacitor packaging structure and a method of manufacturing the same, and an electronic device. The stacked capacitor packaging structure includes a capacitor unit having a plurality of capacitor elements, an insulating package body for partially enclosing the capacitor elements, and a terminal electrode structure having a first electrode structure layer and a second electrode structure layer. The positive electrode portions of the capacitor elements are separate from each other by a predetermined distance, and the negative electrode portions of the capacitor elements are stacked in sequence to provide a lateral common negative electrode structure. A positive side surface of the positive electrode portion of each capacitor element is exposed by the first side portion of the insulating package body. At least one negative side surface of the lateral common negative electrode structure is exposed by the second side portion of the insulating package body.

### CROSS-REFERENCE TO RELATED PATENT APPLICATION

This application claims the benefit of priority to Taiwan Patent Application No. 114110429, filed on Mar. 20, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a capacitor packaging structure, and more particularly to a stacked capacitor packaging structure, a method of manufacturing the stacked capacitor packaging structure, and an electronic device using the stacked capacitor packaging structure.

### BACKGROUND OF THE DISCLOSURE

In the related art, when multiple capacitor elements of the stacked capacitor are stacked, the multiple capacitor elements need to be carried on a conductive carrier substrate in advance, and the positive portions of each capacitor element need to be bent and stacked. Therefore, the stacked capacitors of the related art still have room for improvement.

### SUMMARY OF THE DISCLOSURE

In response to the above-referenced technical inadequacy, the present disclosure provides a stacked capacitor packaging structure, a method of manufacturing the stacked capacitor packaging structure, and an electronic device using the stacked capacitor packaging structure.

In order to solve the above-mentioned problems, one of the technical aspects adopted by the present disclosure is to provide a stacked capacitor packaging structure, which includes a capacitor unit, an insulating package body and a terminal electrode structure. The capacitor unit includes a plurality of capacitor elements stacked in sequence and electrically connected to each other. The insulating package body is configured to partially enclose the capacitor elements. The terminal electrode structure includes a first electrode structure layer for covering a first side portion of the insulating package body, and a second electrode structure layer for covering a second side portion of the insulating package body. Each of the capacitor elements has a positive electrode portion and a negative electrode portion, the positive electrode portions of the capacitor elements are separate from each other by a predetermined distance, and the negative electrode portions of the capacitor elements are stacked in sequence to provide a lateral common negative electrode structure. A positive side surface of the positive electrode portion of each of the capacitor elements is exposed by the first side portion of the insulating package body, thereby being directly electrically connected to the first electrode structure layer. At least one negative side surface of the lateral common negative electrode structure that is provided by the negative electrode portions stacked in sequence is exposed by the second side portion of the insulating package body, thereby being directly electrically connected to the second electrode structure layer.

In order to solve the above-mentioned problems, another one of the technical aspects adopted by the present disclosure is to provide an electronic device, which includes a circuit substrate structure and a stacked capacitor packaging structure. The circuit substrate structure has at least one positive pad and at least one negative pad. The stacked capacitor packaging structure is disposed on the circuit substrate structure and electrically connected to the circuit substrate structure. The stacked capacitor packaging structure includes a capacitor unit, an insulating package body and a terminal electrode structure. The capacitor unit includes a plurality of capacitor elements stacked in sequence and electrically connected to each other, the insulating package body is configured to partially enclose the capacitor elements, and the terminal electrode structure includes a first electrode structure layer for covering a first side portion of the insulating package body, and a second electrode structure layer for covering a second side portion of the insulating package body. Each of the capacitor elements has a positive electrode portion and a negative electrode portion, the positive electrode portions of the capacitor elements are separate from each other by a predetermined distance, and the negative electrode portions of the capacitor elements are stacked in sequence to provide a lateral common negative electrode structure. A positive side surface of the positive electrode portion of each of the capacitor elements is exposed by the first side portion of the insulating package body, thereby being directly electrically connected to the first electrode structure layer. At least one negative side surface of the lateral common negative electrode structure that is provided by the negative electrode portions stacked in sequence is exposed by the second side portion of the insulating package body, thereby being directly electrically connected to the second electrode structure layer.

In order to solve the above-mentioned problems, yet another one of the technical aspects adopted by the present disclosure is to provide a method of manufacturing a stacked capacitor packaging structure, which includes processes of: stacking a plurality of capacitor elements in sequence, in which each of the capacitor elements has a positive electrode portion, a negative electrode portion, and a temporary carrier portion extending from the positive electrode portion, and the negative electrode portions of the capacitor elements are stacked in sequence to provide a lateral common negative electrode structure; forming an insulating package body to partially enclose the capacitor elements, in which at least one negative side surface of the lateral common negative electrode structure that is provided by the negative electrode portions stacked in sequence is exposed by a second side portion of the insulating package body, and the temporary carrier portion of each of the capacitor elements is exposed from the insulating package body; forming a first side electrode material on the insulating package body; removing the temporary carrier portion of each of the capacitor elements to expose a positive side surface of the positive electrode portion of each of the capacitor elements from a first side portion of the insulating package body; and forming a second side electrode material on the insulating package body. The first side electrode material and the second side electrode material are configured to cooperate with each other to form a terminal electrode structure, and the terminal electrode structure includes a first electrode structure layer and a second electrode structure layer. The first electrode structure layer of the terminal electrode structure is configured to enclose the first side portion of the insulating package body and directly electrically connect to the positive side surface of the positive electrode portion of each of the capacitor elements. The second electrode structure layer of the terminal electrode structure is configured to enclose the second side portion of the insulating package body and directly electrically connect to the at least one negative side surface of the lateral common negative electrode structure.

In one of the possible or preferred embodiments, in the process of stacking the capacitor elements in sequence, the positive electrode portion of each of the capacitor elements is configured as a positive conductive pin portion extending horizontally without bending, and the lateral common negative electrode structure that is provided by the negative electrode portions stacked in sequence is configured as a negative conductive common portion without being supported by a conductive carrier substrate.

In one of the possible or preferred embodiments, in the process of stacking the capacitor elements in sequence, the positive electrode portions of the capacitor elements are separate from each other, the negative electrode portions of the capacitor elements are stacked in sequence and electrically connected to each other, and the temporary carrier portions of the capacitor elements are stacked in sequence to form a temporary support structure.

In one of the possible or preferred embodiments, in the process of forming the insulating package body to partially enclose the capacitor elements, the at least one negative side surface of the lateral common negative electrode structure is completely or partially exposed by the second side portion of the insulating package body.

In one of the possible or preferred embodiments, in the process of forming the first side electrode material on the insulating package body, the first side electrode material includes a first bottom electrode portion disposed on a first partial bottom surface of the insulating package body, and a second bottom electrode portion disposed on a second partial bottom surface of the insulating package body.

In one of the possible or preferred embodiments, in the process of removing the temporary carrier portion of each of the capacitor elements, the positive side surface of the positive electrode portion of each of the capacitor elements is completely or partially exposed by the first side portion of the insulating package body.

In one of the possible or preferred embodiments, in the process of forming the second side electrode material on the insulating package body, the first electrode structure layer includes a first side electrode portion disposed on a first side surface of the insulating package body and electrically connected to the first bottom electrode portion, and a second side electrode portion disposed on a second side surface of the insulating package body and electrically connected to the second bottom electrode portion.

Therefore, in the stacked capacitor packaging structure and the electronic device using the stacked capacitor packaging structure provided by the present disclosure, by virtue of “the positive electrode portions of the capacitor elements being separate from each other by a predetermined distance,” “the negative electrode portions of the capacitor elements being stacked in sequence to provide a lateral common negative electrode structure,” “a positive side surface of the positive electrode portion of each of the capacitor elements being exposed by the first side portion of the insulating package body” and “at least one negative side surface of the lateral common negative electrode structure that is provided by the negative electrode portions stacked in sequence being exposed by the second side portion of the insulating package body,” the positive side surface of the positive electrode portion of each of the capacitor elements can be directly electrically connected to the first electrode structure layer, and the at least one negative side surface of the lateral common negative electrode structure that is provided by the negative electrode portions stacked in sequence can be directly electrically connected to the second electrode structure layer. Therefore, the stacked capacitor packaging structure can be configured as a chip-type capacitor packaging structure that can be extended horizontally without bending and being supported by a conductive carrier substrate.

Furthermore, in the stacked capacitor packaging structure and the electronic device using the stacked capacitor packaging structure provided by the present disclosure, by virtue of “stacking a plurality of capacitor elements in sequence, in which each of the capacitor elements has a positive electrode portion, a negative electrode portion, and a temporary carrier portion extending from the positive electrode portion, and the negative electrode portions of the capacitor elements are stacked in sequence to provide a lateral common negative electrode structure,” “forming an insulating package body to partially enclose the capacitor elements, in which at least one negative side surface of the lateral common negative electrode structure that is provided by the negative electrode portions stacked in sequence is exposed by a second side portion of the insulating package body, and the temporary carrier portion of each of the capacitor elements is exposed from the insulating package body,” “forming a first side electrode material on the insulating package body,” “removing the temporary carrier portion of each of the capacitor elements to expose a positive side surface of the positive electrode portion of each of the capacitor elements from a first side portion of the insulating package body,” “forming a second side electrode material on the insulating package body” and “the first side electrode material and the second side electrode material being configured to cooperate with each other to form a terminal electrode structure, and the terminal electrode structure including a first electrode structure layer and a second electrode structure layer,” the positive side surface of the positive electrode portion of each of the capacitor elements can be directly electrically connected to the first electrode structure layer, and the at least one negative side surface of the lateral common negative electrode structure that is provided by the negative electrode portions stacked in sequence can be directly electrically connected to the second electrode structure layer. Therefore, the stacked capacitor packaging structure can be configured as a chip-type capacitor packaging structure that can be extended horizontally without bending and being supported by a conductive carrier substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method of manufacturing a stacked capacitor packaging structure provided by a first embodiment of the present disclosure;

FIG. 2 is a schematic cross-sectional view of an original capacitor element (before cutting) provided by the first embodiment of the present disclosure;

FIG. 3 is a schematic enlarged view of part III of FIG. 2;

FIG. 4 is a schematic side cross-sectional view of step S100 of the method of manufacturing the stacked capacitor packaging structure provided by the first embodiment of the present disclosure;

FIG. 5 is a schematic top view of step S100 of the method of manufacturing the stacked capacitor packaging structure provided by the first embodiment of the present disclosure;

FIG. 6 is a schematic side cross-sectional view of step S102 and step S104 of the method of manufacturing the stacked capacitor packaging structure provided by the first embodiment of the present disclosure;

FIG. 7 is a schematic side cross-sectional view of step S106 of the method of manufacturing the stacked capacitor packaging structure provided by the first embodiment of the present disclosure;

FIG. 8 is a schematic side cross-sectional view of step S108 of the method of manufacturing the stacked capacitor packaging structure provided by the first embodiment of the present disclosure (or a schematic side cross-sectional view of the stacked capacitor packaging structure provided by the first embodiment of the present disclosure);

FIG. 9 is a schematic side cross-sectional view of an electronic device using the stacked capacitor packaging structure provided by a second embodiment of the present disclosure; and

FIG. 10 is a schematic side cross-sectional view of the stacked capacitor packaging structure provided by a third embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” may include plural reference, and the meaning of “in” may include “in” and “on.” Titles or subtitles can be used herein for the convenience of a reader, which shall have no influence on the scope of the present disclosure.

The terms used herein generally have their ordinary meanings in the art. In the case of conflict, the present document, may include any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification may include examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

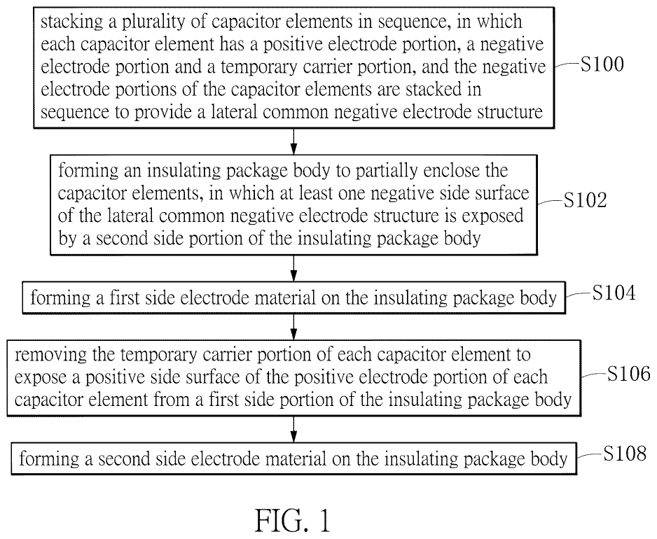

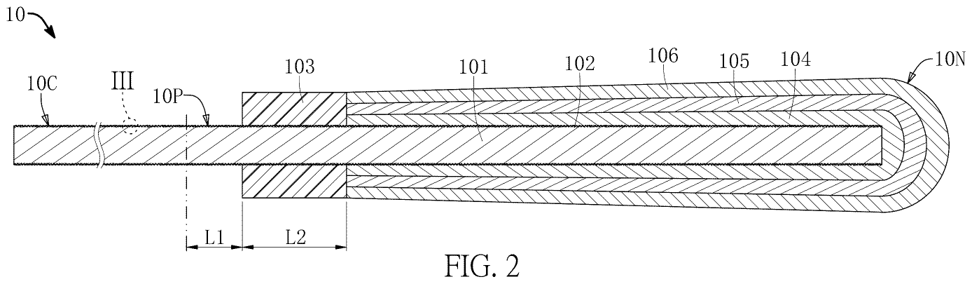

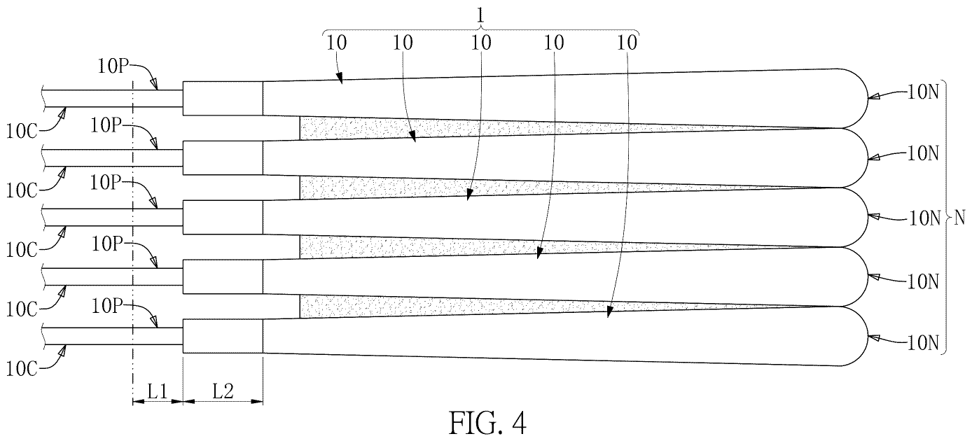

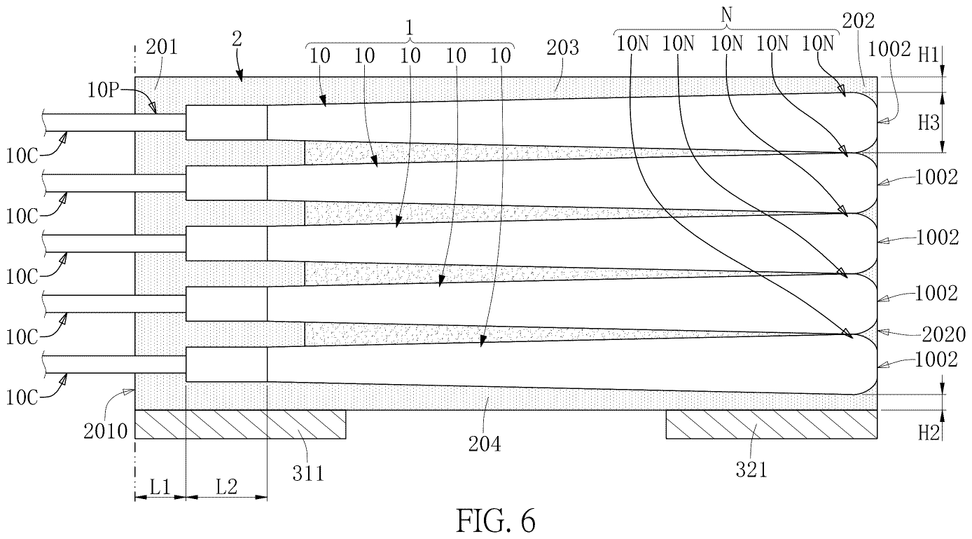

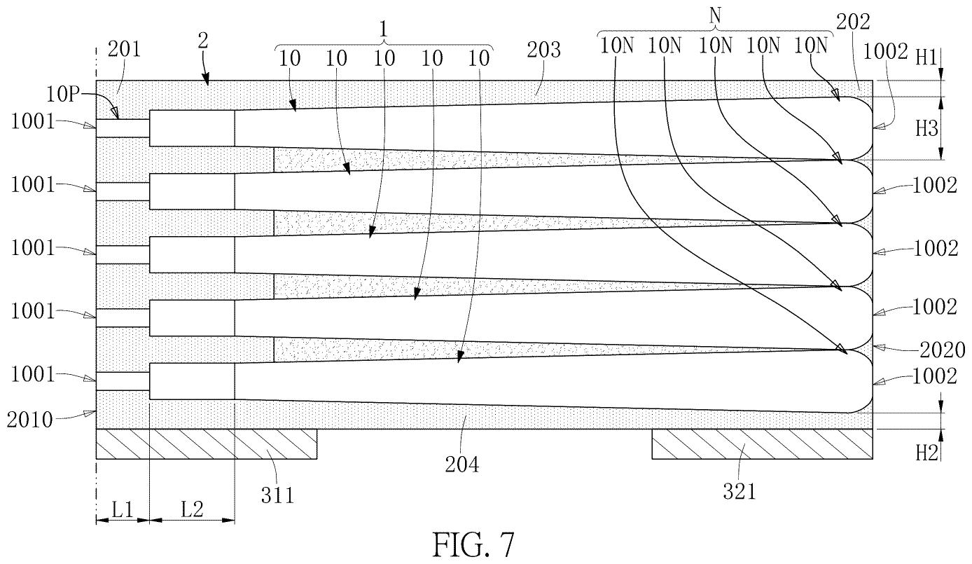

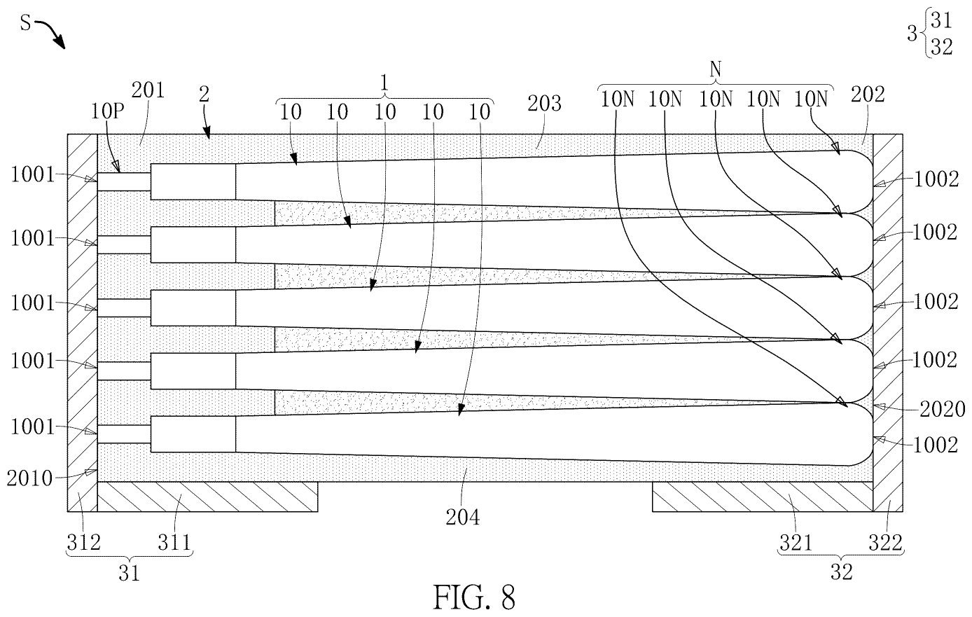

Referring to FIG. 1 to FIG. 8, a first embodiment of the present disclosure provides a method of manufacturing a stacked capacitor packaging structure S, which may at least include the following processes: firstly, referring to FIG. 1, FIG. 2 and FIG. 4, stacking a plurality of capacitor elements 10 (or chip type capacitor elements) in sequence, in which each of the capacitor elements 10 has a positive electrode portion 10P (or an anode portion), a negative electrode portion 10N (or a cathode portion), and a temporary carrier portion 10C (or a removable carrier portion) extending from the positive electrode portion 10P, and the negative electrode portions 10N of the capacitor elements 10 can be stacked in sequence to provide a lateral common negative electrode structure N (step S100); next, referring to FIG. 1, FIG. 4 and FIG. 6, forming an insulating package body 2 (such as any insulating body that can be made of epoxy, silicone or any insulating material) to partially enclose (cover or encapsulate) the capacitor elements 10 (the capacitor elements 10 can be stacked in sequence to form a capacitor unit 1), in which at least one negative side surface 1002 (such as five negative side surfaces 1002 as an example for illustration in FIG. 6, in which each negative side surface 1002 may be a negative electrode processing surface such as a circular arc surface or a curved surface) of the lateral common negative electrode structure N that is provided by the negative electrode portions 10N stacked in sequence can be exposed by a second side portion 202 of the insulating package body 2 (for example, after grinding the insulating package body 2, the negative electrode processing surface of the lateral common negative electrode structure N can be exposed from the insulating package body 2), and the temporary carrier portion 10C of each of the capacitor elements 10 can be exposed from the insulating package body 2 (step S102); then, referring to FIG. 1 and FIG. 6, forming a first side electrode material (such as may include a first bottom electrode portion 311 and a second bottom electrode portion 321) on the insulating package body 2 by electroplating, coating, spraying, printing, dipping or any conductive material forming method (step S104); afterward, referring to FIG. 1, FIG. 6 and FIG. 7, along the cutting line shown in FIG. 6, removing (such as cutting off) the temporary carrier portion 10C of each of the capacitor elements 10 to expose a positive side surface 1001 (such as a flat positive cutting surface, or a positive electrode cutting surface) of the positive electrode portion 10P of each of the capacitor elements 10 from a first side portion 201 of the insulating package body 2 (step S106); next, referring to FIG. 1, FIG. 7 and FIG. 8, forming a second side electrode material (such as may include a first side electrode portion 312 and a second side electrode portion 322) on the insulating package body 2 by electroplating, coating, spraying, printing, dipping or any conductive material forming method (step S108). It should be noted that as shown in FIG. 8, the first side electrode material and the second side electrode material can be configured to cooperate with each other to form a terminal electrode structure 3, and the terminal electrode structure 3 may include a first electrode structure layer 31 and a second electrode structure layer 32. More particularly, the first electrode structure layer 31 of the terminal electrode structure 3 can be configured to enclose (cover or encapsulate) the first side portion 201 of the insulating package body 2 and directly electrically connect to the positive side surface 1001 of the positive electrode portion 10P of each of the capacitor elements 10, and the second electrode structure layer 32 of the terminal electrode structure 3 can be configured to enclose (cover or encapsulate) the second side portion 202 of the insulating package body 2 and directly electrically connect to the at least one negative side surface 1002 of the lateral common negative electrode structure N. However, the aforementioned details are disclosed for exemplary purposes only, and are not meant to limit the scope of the present disclosure.

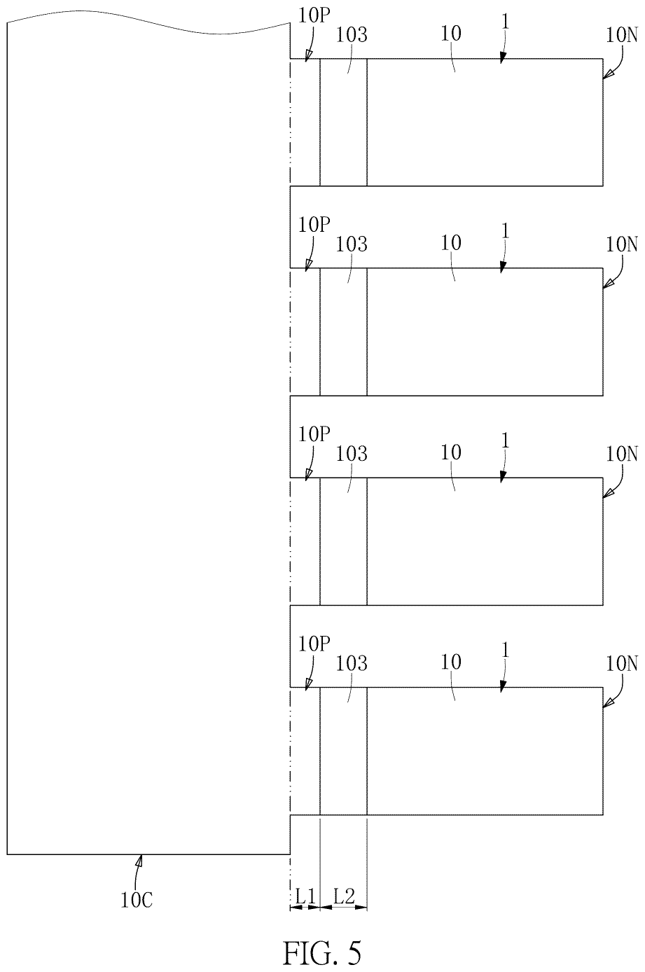

For example, as shown in FIG. 4, in the process (the step S100) of stacking the capacitor elements 10 in sequence, the positive electrode portion 10P of each of the capacitor elements 10 can be configured as a positive conductive pin portion extending horizontally (or approximately horizontally) without bending, and the lateral common negative electrode structure N that is provided by the negative electrode portions 10N stacked in sequence can be configured as a negative conductive common portion without being supported by a conductive carrier substrate (that is to say, only the capacitor elements 10 can be stacked in sequence and electrically connected to each other). In addition, as shown in FIG. 4, in the process (the step S100) of stacking the capacitor elements 10 in sequence, the positive electrode portions 10P of the capacitor elements 10 can be separate from each other, and the negative electrode portions 10N of the capacitor elements 10 can be stacked in sequence and electrically connected to each other. It should be noted that referring to FIG. 4 and FIG. 5, in the process (the step S100) of stacking the capacitor elements 10 in sequence, the multiple rear sections of the temporary carrier portions 10C of the capacitor elements 10 can be stacked in sequence to form a temporary support structure (as shown in FIG. 4, the multiple front sections of the temporary carrier portions 10C near the positive electrode portions 10P can be separated from each other), and the temporary support structure can be configured to simultaneously support the capacitor units 1 (each capacitor unit 1 may include the capacitor elements 10). However, the aforementioned details are disclosed for exemplary purposes only, and are not meant to limit the scope of the present disclosure.

For example, as shown in FIG. 6, in the process (the step S102) of forming the insulating package body 2 to partially enclose the capacitor elements 10, the at least one negative side surface 1002 of the lateral common negative electrode structure N can be completely or partially exposed by the second side portion 202 of the insulating package body 2 (for example, FIG. 6 shows that the five negative side surface 1002 of the lateral common negative electrode structure N can be partially exposed by the second side portion 202 of the insulating package body 2). Furthermore, as shown in FIG. 6, in the process (the step S104) of forming the first side electrode material on the insulating package body 2, the first side electrode material may include a first bottom electrode portion 311 disposed on a first partial bottom surface of the insulating package body 2, and a second bottom electrode portion 321 disposed on a second partial bottom surface of the insulating package body 2. Moreover, as shown in FIG. 7, in the process (the step S106) of removing the temporary carrier portion 10C of each of the capacitor elements 10, the positive side surface 1001 (such as a flat positive cutting surface, or a positive electrode cutting surface) of the positive electrode portion 10P of each of the capacitor elements 10 can be completely or partially exposed by the first side portion 201 of the insulating package body 2. In addition, as shown in FIG. 8, in the process (the step S108) of forming the second side electrode material on the insulating package body 2, the first electrode structure layer 31 may include a first side electrode portion 312 disposed on a first side surface 2010 of the insulating package body 2 and electrically connected to the first bottom electrode portion 311, and a second side electrode portion 322 disposed on a second side surface 2020 of the insulating package body 2 and electrically connected to the second bottom electrode portion 321. However, the aforementioned details are disclosed for exemplary purposes only, and are not meant to limit the scope of the present disclosure.

Furthermore, referring to FIG. 1 to FIG. 8, through the method of manufacturing the stacked capacitor packaging structure S provided by the first embodiment of the present disclosure, the first embodiment of the present disclosure can further provide a stacked capacitor packaging structure S, which may at least include a capacitor unit 1 (or a capacitor assembly), an insulating package body 2 and a terminal electrode structure 3. More particularly, the capacitor unit 1 may include a plurality of capacitor elements 10 stacked in sequence and electrically connected to each other, in which each of the capacitor elements 10 has a positive electrode portion 10P and a negative electrode portion 10N, the positive electrode portions 10P of the capacitor elements 10 can be separate from each other by a predetermined distance, and the negative electrode portions 10N of the capacitor elements 10 can be stacked in sequence to provide a lateral common negative electrode structure N (or a common negative terminal structure). In addition, the insulating package body 2 can be configured to partially enclose (cover or encapsulate) the capacitor elements 10, and the terminal electrode structure 3 may include a first electrode structure layer 31 for covering (or enclosing) a first side portion 201 of the insulating package body 2, and a second electrode structure layer 32 for covering (or enclosing) a second side portion 202 of the insulating package body 2.

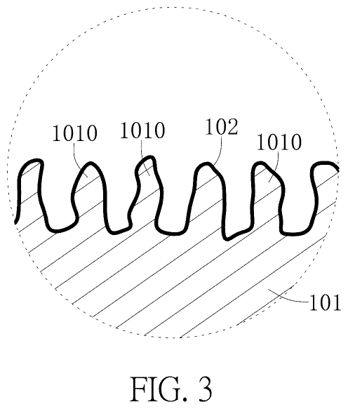

For example, referring to FIG. 2, FIG. 3 and FIG. 8, each of the capacitor elements 10 may include a metal foil 101 (such as aluminum foil, copper foil or any kind of conductive foil), an oxide layer 102 formed on the metal foil 101, a surrounding insulating layer 103 surroundingly disposed on the oxide layer 102, a conductive polymer layer 104 for connecting the surrounding insulating layer 103 and partially covering (or enclosing) the oxide layer 102, and a conductive adhesive structure layer for connecting the surrounding insulating layer 103 and completely covering (or enclosing) the conductive polymer layer 104, and the metal foil 101 has a porous corrosion structure 1010 covered (or enclosed) by the oxide layer 102. In addition, the conductive adhesive structure layer may include a carbon adhesive layer 105 for completely covering (enclosing) the conductive polymer layer 104, and a silver glue layer 106 for completely covering (enclosing) the carbon adhesive layer 105, and the length L1 (or the length L1 along the extending direction of the metal foil 101) of the positive electrode portion 10P of the capacitor element 10 can be less than the length L2 (or the length L2 along the extending direction of the metal foil 101) of the surrounding insulating layer 103. It should be noted that referring to FIG. 4 and FIG. 8, the positive electrode portion 10P of each of the capacitor elements 10 can be configured as a positive conductive pin portion extending horizontally (or approximately horizontally) without being bent, and the lateral common negative electrode structure N that is provided by the negative electrode portions 10N stacked in sequence can be configured as a negative conductive common portion without being supported by a conductive carrier substrate (such as a lead frame). However, the aforementioned details are disclosed for exemplary purposes only, and are not meant to limit the scope of the present disclosure.

For example, referring to FIG. 2, FIG. 4 and FIG. 8, a positive side surface 1001 of the positive electrode portion 10P of each of the capacitor elements 10 can be completely or partially exposed by the first side portion 201 of the insulating package body 2 (that is to say, the positive side surface 1001 of the positive electrode portion 10P of each of the capacitor elements 10 is not completely covered by the insulating package body 2), so that the positive side surface 1001 of the positive electrode portion 10P of each of the capacitor elements 10 can be directly electrically connected to the first electrode structure layer 31. In addition, at least one negative side surface 1002 (or multiple negative side surfaces 1002) of the lateral common negative electrode structure N that is provided by the negative electrode portions 10N stacked in sequence can be completely or partially exposed by the second side portion 202 of the insulating package body 2 (that is to say, the at least one negative side surface 1002 or the multiple negative side surfaces 1002 of the lateral common negative electrode structure N are not completely covered by the insulating package body 2), so that the at least one negative side surface 1002 (or the multiple negative side surfaces 1002) of the lateral common negative electrode structure N can be directly electrically connected to the second electrode structure layer 32. In other words, the positive side surface 1001 of the positive electrode portion 10P of each of the capacitor elements 10 can be exposed from a first side surface 2010 of the first side portion 201 of the insulating package body 2, so that the first electrode structure layer 31 can be configured to directly electrically contact the positive side surface 1001 of the positive electrode portion 10P of each of the capacitor elements 10. In addition, the at least one negative side surface 1002 of the lateral common negative electrode structure N that is provided by the negative electrode portions 10N stacked in sequence can be exposed from a second side surface 2020 of the second side portion 202 of the insulating package body 2, so that the second electrode structure layer 32 can be configured to directly electrically contact the at least one negative side surface 1002 (or the multiple negative side surfaces 1002) of the lateral common negative electrode structure N. However, the aforementioned details are disclosed for exemplary purposes only, and are not meant to limit the scope of the present disclosure.

For example, referring to FIG. 2, FIG. 6 and FIG. 8, a top side of a topmost one of the capacitor elements 10 can only contact the insulating package body 2, and a bottom side of a bottommost one of the capacitor elements 10 can only contact the insulating package body 2. More particularly, the insulating package body 2 has a top packaging portion 203 located between the top side of the topmost capacitor element 10 and an upper surface of the insulating package body 2, and the insulating package body 2 has a bottom packaging portion 204 located between the bottom side of the bottommost capacitor element 10 and a lower surface of the insulating package body 2. It should be noted that the minimum thickness H1 (or maximum thickness, or average thickness) of the top packaging portion 203 and the minimum thickness H2 (or maximum thickness, or average thickness) of the bottom packaging portion 204 are both less than the maximum thickness H3 (or minimum thickness, or average thickness) of each of the capacitor elements 10, and a volume occupied by the top packaging portion 203 of the insulating package body 2 and a volume occupied by the bottom packaging portion 204 of the insulating package body 2 are both less than a volume occupied by each of the capacitor elements 10. However, the aforementioned details are disclosed for exemplary purposes only, and are not meant to limit the scope of the present disclosure.

For example, referring to FIG. 6, FIG. 7 and FIG. 8, the first electrode structure layer 31 may include a first bottom electrode portion 311 and a first side electrode portion 312, the first bottom electrode portion 311 can be disposed on a first partial bottom surface of the insulating package body 2, and the first side electrode portion 312 can be disposed on a first side surface 2010 of the insulating package body 2 and electrically connected to the first bottom electrode portion 311. In addition, the second electrode structure layer 32 may include a second bottom electrode portion 321 and a second side electrode portion 322, the second bottom electrode portion 321 can be disposed on a second partial bottom surface of the insulating package body 2, and the second side electrode portion 322 can be disposed on a second side surface 2020 of the insulating package body 2 and electrically connected to the second bottom electrode portion 321. It should be noted that the positive side surface 1001 of the positive electrode portion 10P of each of the capacitor elements 10 can directly contact the first side electrode portion 312 of the first electrode structure layer 31 and be separate from the first bottom electrode portion 311 of the first electrode structure layer 31, and the at least one negative side surface 1002 (or the multiple negative side surfaces 1002) of the lateral common negative electrode structure N that is provided by sequentially stacking the negative electrode portions 10N can directly contact the second side electrode portion 322 of the second electrode structure layer 32 and be separate from the second bottom electrode portion 321 of the second electrode structure layer 32. However, the aforementioned details are disclosed for exemplary purposes only, and are not meant to limit the scope of the present disclosure.

Therefore, as shown in FIG. 8, the stacked capacitor packaging structure S provided by the first embodiment of the present disclosure can be configured as a chip-type capacitor packaging structure without being bent (i.e., without bending the positive conductive pin portion) and without being supported by a conductive carrier substrate (such as a lead frame). That is to say, the positive electrode portions 10P of the capacitor elements 10 can directly contact the first side electrode portion 312 of the first electrode structure layer 31, and the negative electrode portions 10N (or the lateral common negative electrode structure N) of the capacitor elements 10 can directly contact the second side electrode portion 322 of the second electrode structure layer 32, so that the stacked capacitor packaging structure S provided by the first embodiment of the present disclosure can achieve the benefits and advantages of reducing the volume (or reducing the thickness and length), increasing the capacitance (i.e., increasing the number of stacked layers of the capacitor elements 10), reducing the impedance (i.e., reducing the positive conductive path and the negative conductive path), and reducing the manufacturing cost (i.e., without bending the positive electrode pin portions and using a conductive carrier substrate).

### Second Embodiment

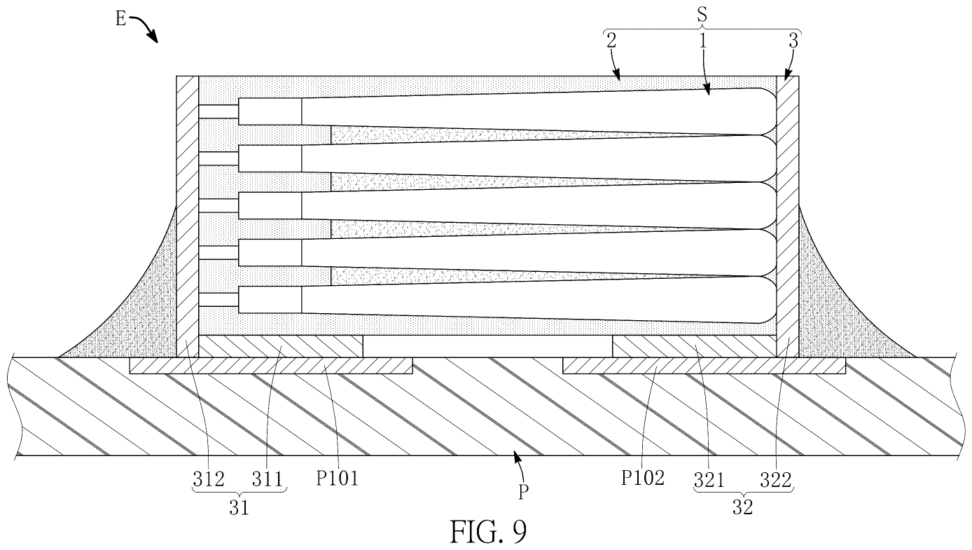

Referring to FIG. 9, a second embodiment of the present disclosure provides an electronic device E (or an electronic carrier module, or an electronic component module), which includes a circuit substrate structure P and a stacked capacitor packaging structure S provided by the first embodiment. Comparing FIG. 9 with FIG. 8, the main difference between the second embodiment and the first embodiment is as follows: in the second embodiment, the circuit substrate structure P may have at least one positive pad P101 and at least one negative pad P102, and the stacked capacitor packaging structure S provided by the first embodiment can be disposed (or bonded) on the circuit substrate structure P and electrically connected to the circuit substrate structure P through the conductive materials. It should be noted that the electronic device E may be a desktop computer, a notebook computer, a tablet computer or any other electronic device, and the circuit substrate structure P of the electronic device E may be configured to carry any type of electronic components, such as a control chip, a memory chip, an inductor, a resistor or any type of semiconductor chip. However, the aforementioned details are disclosed for exemplary purposes only, and are not meant to limit the scope of the present disclosure.

### Third Embodiment

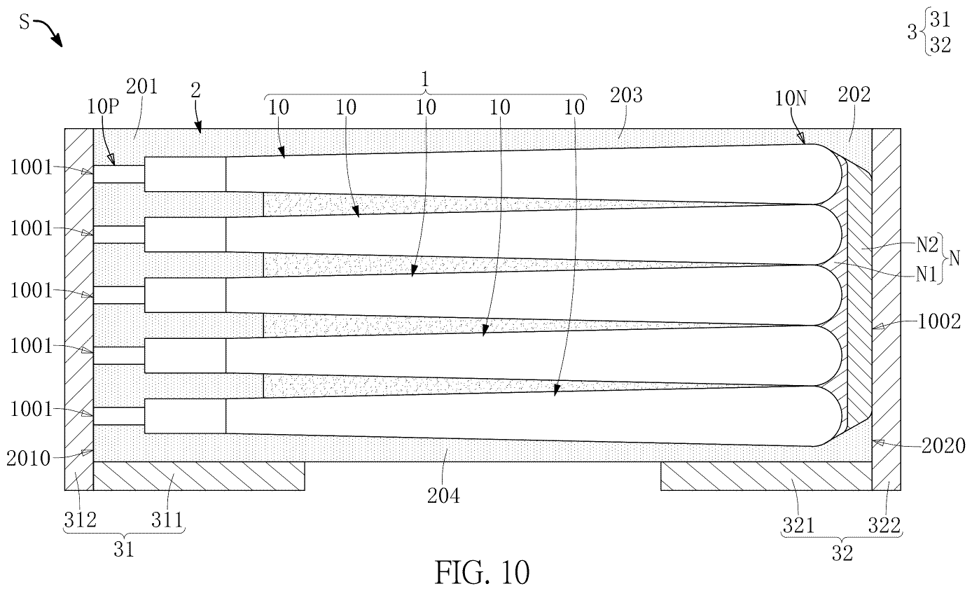

Referring to FIG. 10, a third embodiment of the present disclosure provides a stacked capacitor packaging structure S, which may at least include a capacitor unit 1, an insulating package body 2 and a terminal electrode structure 3. Comparing FIG. 10 with FIG. 8, the main difference between the third embodiment and the first embodiment is as follows: in the third embodiment, the lateral common negative electrode structure N that is provided by the negative electrode portions 10N stacked in sequence can be configured as a thickened conductive adhesive structure (or a single-layer conductive adhesive structure) or a composite conductive adhesive structure (or a multi-layer conductive adhesive structure).

For example, as shown in FIG. 2 and FIG. 10, when the lateral common negative electrode structure N can be configured as the composite conductive adhesive structure, the lateral common negative electrode structure N may include a negative base portion N1 formed by sequentially connecting the silver glue layers 106 of the capacitor elements 10 (or a first conductive adhesive layer for connecting the silver glue layers 106 of the capacitor elements 10, which can use the same or different conductive material as the silver glue layer 106 as shown in FIG. 2) and a negative thickening portion N2 disposed on the negative base portion N1 (or a second conductive adhesive layer for connecting or covering the first conductive adhesive layer, which can use the same or different conductive material as the silver glue layer 106), and the at least one negative side surfaces 1002 can be provided by the negative thickening portion N2. It should be noted that the negative thickening portion N2 can be configured to gradually shrink toward the second electrode structure layer 32, so that the lateral common negative electrode structure N can present a tapered shape. However, the aforementioned details are disclosed for exemplary purposes only, and are not meant to limit the scope of the present disclosure.

For example, when the lateral common negative electrode structure N can be configured as the thickened conductive adhesive structure, the lateral common negative electrode structure N can be formed by sequentially connecting the silver glue layers 106 of the capacitor elements 10 (as shown in FIG. 2). That is to say, the lateral common negative electrode structure N can be configured as a negative base portion N1 formed by sequentially connecting the silver glue layers 106 of the capacitor elements 10 (or a first conductive adhesive layer for connecting the silver glue layers 106 of the capacitor elements 10, which can use the same or different conductive material as the silver glue layer 106 as shown in FIG. 2), and the lateral common negative electrode structure N may not use a negative thickening portion N2 disposed on the negative base portion N1, so that the at least one negative side surfaces 1002 can be provided by the negative base portion N1. It should be noted that the lateral common negative electrode structure N (i.e., the negative base portion N1) can be configured to gradually shrink toward the second electrode structure layer 32, so that the lateral common negative electrode structure N can present a tapered shape. However, the aforementioned details are disclosed for exemplary purposes only, and are not meant to limit the scope of the present disclosure.

### [Beneficial Effects of the Embodiments]

In conclusion, in the stacked capacitor packaging structure S and the electronic device E using the stacked capacitor packaging structure S provided by the present disclosure, by virtue of “the positive electrode portions 10P of the capacitor elements 10 being separate from each other by a predetermined distance,” “the negative electrode portions 10N of the capacitor elements 10 being stacked in sequence to provide a lateral common negative electrode structure N,” “a positive side surface 1001 of the positive electrode portion 10P of each of the capacitor elements 10 being exposed by the first side portion 201 of the insulating package body 2” and “at least one negative side surface 1002 of the lateral common negative electrode structure N that is provided by the negative electrode portions 10N stacked in sequence being exposed by the second side portion 202 of the insulating package body 2,” the positive side surface 1001 of the positive electrode portion 10P of each of the capacitor elements 10 can be directly electrically connected to the first electrode structure layer 31, and the at least one negative side surface 1002 of the lateral common negative electrode structure N that is provided by the negative electrode portions 10N stacked in sequence can be directly electrically connected to the second electrode structure layer 32. Therefore, the stacked capacitor packaging structure S can be configured as a chip-type capacitor packaging structure that can be extended horizontally without bending and being supported by a conductive carrier substrate.

Furthermore, in the stacked capacitor packaging structure S and the electronic device E using the stacked capacitor packaging structure S provided by the present disclosure, by virtue of “stacking a plurality of capacitor elements 10 in sequence, in which each of the capacitor elements 10 has a positive electrode portion 10P, a negative electrode portion 10N, and a temporary carrier portion 10C extending from the positive electrode portion 10P, and the negative electrode portions 10N of the capacitor elements 10 can be stacked in sequence to provide a lateral common negative electrode structure N,” “forming an insulating package body 2 to partially enclose (cover or encapsulate) the capacitor elements 10, in which at least one negative side surface 1002 of the lateral common negative electrode structure N that is provided by the negative electrode portions 10N stacked in sequence can be exposed by a second side portion 202 of the insulating package body 2, and the temporary carrier portion 10C of each of the capacitor elements 10 can be exposed from the insulating package body 2,” “forming a first side electrode material on the insulating package body 2,” “removing the temporary carrier portion 10C of each of the capacitor elements 10 to expose a positive side surface 1001 of the positive electrode portion 10P of each of the capacitor elements 10 from a first side portion 201 of the insulating package body 2,” “forming a second side electrode material on the insulating package body 2” and “the first side electrode material and the second side electrode material being configured to cooperate with each other to form a terminal electrode structure 3, and the terminal electrode structure 3 may include a first electrode structure layer 31 and a second electrode structure layer 32,” the positive side surface 1001 of the positive electrode portion 10P of each of the capacitor elements 10 can be directly electrically connected to the first electrode structure layer 31, and the at least one negative side surface 1002 of the lateral common negative electrode structure N that is provided by the negative electrode portions 10N stacked in sequence can be directly electrically connected to the second electrode structure layer 32. Therefore, the stacked capacitor packaging structure S can be configured as a chip-type capacitor packaging structure that can be extended horizontally without bending and being supported by a conductive carrier substrate.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A stacked capacitor packaging structure, comprising:
a capacitor unit including a plurality of capacitor elements stacked in sequence and electrically connected to each other;
an insulating package body configured to partially enclose the capacitor elements; and
a terminal electrode structure including a first electrode structure layer for covering a first side portion of the insulating package body, and a second electrode structure layer for covering a second side portion of the insulating package body;
wherein each of the capacitor elements has a positive electrode portion and a negative electrode portion, the positive electrode portions of the capacitor elements are separate from each other by a predetermined distance, and the negative electrode portions of the capacitor elements are stacked in sequence to provide a lateral common negative electrode structure;
wherein a positive side surface of the positive electrode portion of each of the capacitor elements is exposed by the first side portion of the insulating package body, thereby being directly electrically connected to the first electrode structure layer; and
wherein at least one negative side surface of the lateral common negative electrode structure that is provided by the negative electrode portions stacked in sequence is exposed by the second side portion of the insulating package body, thereby being directly electrically connected to the second electrode structure layer.

2. The stacked capacitor packaging structure according to claim 1,
wherein each of the capacitor elements includes a metal foil, an oxide layer formed on the metal foil, a surrounding insulating layer surroundingly disposed on the oxide layer, a conductive polymer layer for connecting the surrounding insulating layer and partially covering the oxide layer, and a conductive adhesive structure layer for connecting the surrounding insulating layer and completely covering the conductive polymer layer, and the metal foil has a porous corrosion structure covered by the oxide layer;
wherein the conductive adhesive structure layer includes a carbon adhesive layer for completely covering the conductive polymer layer, and a silver glue layer for completely covering the carbon adhesive layer, and a length of the positive electrode portion of the capacitor element is less than a length of the surrounding insulating layer;
wherein the positive side surface of the positive electrode portion of each of the capacitor elements and the at least one negative side surface of the lateral common negative electrode structure that is provided by the negative electrode portions stacked in sequence are not completely covered by the insulating package body;
wherein the positive electrode portion of each of the capacitor elements is configured as a positive conductive pin portion extending horizontally without bending, and the lateral common negative electrode structure that is provided by the negative electrode portions stacked in sequence is configured as a negative conductive common portion without being supported by a conductive carrier substrate;
wherein the lateral common negative electrode structure that is provided by the negative electrode portions stacked in sequence is configured as a thickened conductive adhesive structure or a composite conductive adhesive structure;
wherein, when the lateral common negative electrode structure is configured as the thickened conductive adhesive structure, the lateral common negative electrode structure is formed by sequentially connecting the silver glue layers of the capacitor elements, and the lateral common negative electrode structure gradually is configured to gradually shrink toward the second electrode structure layer;
wherein, when the lateral common negative electrode structure is configured as the composite conductive adhesive structure, the lateral common negative electrode structure includes a negative base portion formed by sequentially connecting the silver glue layers of the capacitor elements and a negative thickening portion disposed on the negative base portion, and the negative thickening portion is configured to gradually shrink toward the second electrode structure layer;
wherein the positive side surface of the positive electrode portion of each of the capacitor elements is completely or partially exposed by the first side portion of the insulating package body, and the at least one negative side surface of the lateral common negative electrode structure that is provided by the negative electrode portions stacked in sequence is completely or partially exposed by the second side portion of the insulating package body;
wherein the positive side surface of the positive electrode portion of each of the capacitor elements is exposed from a first side surface of the first side portion of the insulating package body, so that the first electrode structure layer is configured to directly electrically contact the positive side surface of the positive electrode portion of each of the capacitor elements; and
wherein the at least one negative side surface of the lateral common negative electrode structure that is provided by the negative electrode portions stacked in sequence is exposed from a second side surface of the second side portion of the insulating package body, so that the second electrode structure layer is configured to directly electrically contact the at least one negative side surface of the lateral common negative electrode structure.

3. The stacked capacitor packaging structure according to claim 1,
wherein a top side of a topmost one of the capacitor elements only contacts the insulating package body, and a bottom side of a bottommost one of the capacitor elements only contacts the insulating package body;
wherein the insulating package body has a top packaging portion located between the top side of the topmost capacitor element and an upper surface of the insulating package body, and the insulating package body has a bottom packaging portion located between the bottom side of the bottommost capacitor element and a lower surface of the insulating package body;
wherein a minimum thickness of the top packaging portion and a minimum thickness of the bottom packaging portion are both less than a maximum thickness of each of the capacitor elements, and a volume occupied by the top packaging portion of the insulating package body and a volume occupied by the bottom packaging portion of the insulating package body are both less than a volume occupied by each of the capacitor elements;
wherein the first electrode structure layer includes a first bottom electrode portion disposed on a first partial bottom surface of the insulating package body, and a first side electrode portion disposed on a first side surface of the insulating package body and electrically connected to the first bottom electrode portion;
wherein the second electrode structure layer includes a second bottom electrode portion disposed on a second partial bottom surface of the insulating package body, and a second side electrode portion disposed on a second side surface of the insulating package body and electrically connected to the second bottom electrode portion;
wherein the positive side surface of the positive electrode portion of each of the capacitor elements is configured as a positive electrode cutting surface, and the at least one negative side surface of the lateral common negative electrode structure that is provided by the negative electrode portions stacked in sequence is configured as a negative electrode processing surface;
wherein the positive side surface of the positive electrode portion of each of the capacitor elements directly contacts the first side electrode portion of the first electrode structure layer and is separate from the first bottom electrode portion of the first electrode structure layer;
wherein the at least one negative side surface of the lateral common negative electrode structure that is provided by sequentially stacking the negative electrode portions directly contacts the second side electrode portion of the second electrode structure layer and is separate from the second bottom electrode portion of the second electrode structure layer; and
wherein the stacked capacitor packaging structure is configured as a chip-type capacitor packaging structure without being bent and without being supported by a conductive carrier substrate.

4. An electronic device, comprising:
a circuit substrate structure having at least one positive pad and at least one negative pad; and
a stacked capacitor packaging structure disposed on the circuit substrate structure and electrically connected to the circuit substrate structure;
wherein the stacked capacitor packaging structure includes a capacitor unit, an insulating package body and a terminal electrode structure;
wherein the capacitor unit includes a plurality of capacitor elements stacked in sequence and electrically connected to each other, the insulating package body is configured to partially enclose the capacitor elements, and the terminal electrode structure includes a first electrode structure layer for covering a first side portion of the insulating package body, and a second electrode structure layer for covering a second side portion of the insulating package body;
wherein each of the capacitor elements has a positive electrode portion and a negative electrode portion, the positive electrode portions of the capacitor elements are separate from each other by a predetermined distance, and the negative electrode portions of the capacitor elements are stacked in sequence to provide a lateral common negative electrode structure;
wherein a positive side surface of the positive electrode portion of each of the capacitor elements is exposed by the first side portion of the insulating package body, thereby being directly electrically connected to the first electrode structure layer; and
wherein at least one negative side surface of the lateral common negative electrode structure that is provided by the negative electrode portions stacked in sequence is exposed by the second side portion of the insulating package body, thereby being directly electrically connected to the second electrode structure layer.

5. The electronic device according to claim 4,
wherein each of the capacitor elements includes a metal foil, an oxide layer formed on the metal foil, a surrounding insulating layer surroundingly disposed on the oxide layer, a conductive polymer layer for connecting the surrounding insulating layer and partially covering the oxide layer, and a conductive adhesive structure layer for connecting the surrounding insulating layer and completely covering the conductive polymer layer, and the metal foil has a porous corrosion structure covered by the oxide layer;
wherein the conductive adhesive structure layer includes a carbon adhesive layer for completely covering the conductive polymer layer, and a silver glue layer for completely covering the carbon adhesive layer, and a length of the positive electrode portion of the capacitor element is less than a length of the surrounding insulating layer;
wherein the positive side surface of the positive electrode portion of each of the capacitor elements and the at least one negative side surface of the lateral common negative electrode structure that is provided by the negative electrode portions stacked in sequence are not completely covered by the insulating package body;
wherein the positive electrode portion of each of the capacitor elements is configured as a positive conductive pin portion extending horizontally without bending, and the lateral common negative electrode structure that is provided by the negative electrode portions stacked in sequence is configured as a negative conductive common portion without being supported by a conductive carrier substrate;
wherein the lateral common negative electrode structure that is provided by the negative electrode portions stacked in sequence is configured as a thickened conductive adhesive structure or a composite conductive adhesive structure;
wherein, when the lateral common negative electrode structure is configured as the thickened conductive adhesive structure, the lateral common negative electrode structure is formed by sequentially connecting the silver glue layers of the capacitor elements, and the lateral common negative electrode structure gradually is configured to gradually shrink toward the second electrode structure layer;
wherein, when the lateral common negative electrode structure is configured as the composite conductive adhesive structure, the lateral common negative electrode structure includes a negative base portion formed by sequentially connecting the silver glue layers of the capacitor elements and a negative thickening portion disposed on the negative base portion, and the negative thickening portion is configured to gradually shrink toward the second electrode structure layer;
wherein the positive side surface of the positive electrode portion of each of the capacitor elements is completely or partially exposed by the first side portion of the insulating package body, and the at least one negative side surface of the lateral common negative electrode structure that is provided by the negative electrode portions stacked in sequence is completely or partially exposed by the second side portion of the insulating package body;
wherein the positive side surface of the positive electrode portion of each of the capacitor elements is exposed from a first side surface of the first side portion of the insulating package body, so that the first electrode structure layer is configured to directly electrically contact the positive side surface of the positive electrode portion of each of the capacitor elements; and
wherein the at least one negative side surface of the lateral common negative electrode structure that is provided by the negative electrode portions stacked in sequence is exposed from a second side surface of the second side portion of the insulating package body, so that the second electrode structure layer is configured to directly electrically contact the at least one negative side surface of the lateral common negative electrode structure.

6. The electronic device according to claim 4,
wherein a top side of a topmost one of the capacitor elements only contacts the insulating package body, and a bottom side of a bottommost one of the capacitor elements only contacts the insulating package body;
wherein the insulating package body has a top packaging portion located between the top side of the topmost capacitor element and an upper surface of the insulating package body, and the insulating package body has a bottom packaging portion located between the bottom side of the bottommost capacitor element and a lower surface of the insulating package body;
wherein a minimum thickness of the top packaging portion and a minimum thickness of the bottom packaging portion are both less than a maximum thickness of each of the capacitor elements, and a volume occupied by the top packaging portion of the insulating package body and a volume occupied by the bottom packaging portion of the insulating package body are both less than a volume occupied by each of the capacitor elements;
wherein the first electrode structure layer includes a first bottom electrode portion disposed on a first partial bottom surface of the insulating package body, and a first side electrode portion disposed on a first side surface of the insulating package body and electrically connected to the first bottom electrode portion;
wherein the second electrode structure layer includes a second bottom electrode portion disposed on a second partial bottom surface of the insulating package body, and a second side electrode portion disposed on a second side surface of the insulating package body and electrically connected to the second bottom electrode portion;
wherein the positive side surface of the positive electrode portion of each of the capacitor elements is configured as a positive electrode cutting surface, and the at least one negative side surface of the lateral common negative electrode structure that is provided by the negative electrode portions stacked in sequence is configured as a negative electrode processing surface;
wherein the positive side surface of the positive electrode portion of each of the capacitor elements directly contacts the first side electrode portion of the first electrode structure layer and is separate from the first bottom electrode portion of the first electrode structure layer;
wherein the at least one negative side surface of the lateral common negative electrode structure that is provided by sequentially stacking the negative electrode portions directly contacts the second side electrode portion of the second electrode structure layer and is separate from the second bottom electrode portion of the second electrode structure layer; and
wherein the stacked capacitor packaging structure is configured as a chip-type capacitor packaging structure without being bent and without being supported by a conductive carrier substrate.

7. A method of manufacturing a stacked capacitor packaging structure, comprising processes of:
stacking a plurality of capacitor elements in sequence, wherein each of the capacitor elements has a positive electrode portion, a negative electrode portion, and a temporary carrier portion extending from the positive electrode portion, and the negative electrode portions of the capacitor elements are stacked in sequence to provide a lateral common negative electrode structure;
forming an insulating package body to partially enclose the capacitor elements, wherein at least one negative side surface of the lateral common negative electrode structure that is provided by the negative electrode portions stacked in sequence is exposed by a second side portion of the insulating package body, and the temporary carrier portion of each of the capacitor elements is exposed from the insulating package body;
forming a first side electrode material on the insulating package body;
removing the temporary carrier portion of each of the capacitor elements to expose a positive side surface of the positive electrode portion of each of the capacitor elements from a first side portion of the insulating package body; and
forming a second side electrode material on the insulating package body;
wherein the first side electrode material and the second side electrode material are configured to cooperate with each other to form a terminal electrode structure, and the terminal electrode structure includes a first electrode structure layer and a second electrode structure layer;
wherein the first electrode structure layer of the terminal electrode structure is configured to enclose the first side portion of the insulating package body and directly electrically connect to the positive side surface of the positive electrode portion of each of the capacitor elements; and
wherein the second electrode structure layer of the terminal electrode structure is configured to enclose the second side portion of the insulating package body and directly electrically connect to the at least one negative side surface of the lateral common negative electrode structure.

8. The method according to claim 7,
wherein, in the process of stacking the capacitor elements in sequence, the positive electrode portion of each of the capacitor elements is configured as a positive conductive pin portion extending horizontally without bending, and the lateral common negative electrode structure that is provided by the negative electrode portions stacked in sequence is configured as a negative conductive common portion without being supported by a conductive carrier substrate;
wherein, in the process of stacking the capacitor elements in sequence, the positive electrode portions of the capacitor elements are separate from each other, the negative electrode portions of the capacitor elements are stacked in sequence and electrically connected to each other, and the temporary carrier portions of the capacitor elements are stacked in sequence to form a temporary support structure;
wherein, in the process of forming the insulating package body to partially enclose the capacitor elements, the at least one negative side surface of the lateral common negative electrode structure is completely or partially exposed by the second side portion of the insulating package body;
wherein, in the process of forming the first side electrode material on the insulating package body, the first side electrode material includes a first bottom electrode portion disposed on a first partial bottom surface of the insulating package body, and a second bottom electrode portion disposed on a second partial bottom surface of the insulating package body;
wherein, in the process of removing the temporary carrier portion of each of the capacitor elements, the positive side surface of the positive electrode portion of each of the capacitor elements is completely or partially exposed by the first side portion of the insulating package body; and
wherein, in the process of forming the second side electrode material on the insulating package body, the first electrode structure layer includes a first side electrode portion disposed on a first side surface of the insulating package body and electrically connected to the first bottom electrode portion, and a second side electrode portion disposed on a second side surface of the insulating package body and electrically connected to the second bottom electrode portion.

9. The method according to claim 7,
wherein each of the capacitor elements includes a metal foil, an oxide layer formed on the metal foil, a surrounding insulating layer surroundingly disposed on the oxide layer, a conductive polymer layer for connecting the surrounding insulating layer and partially covering the oxide layer, and a conductive adhesive structure layer for connecting the surrounding insulating layer and completely covering the conductive polymer layer, and the metal foil has a porous corrosion structure covered by the oxide layer;
wherein the conductive adhesive structure layer includes a carbon adhesive layer for completely covering the conductive polymer layer, and a silver glue layer for completely covering the carbon adhesive layer, and a length of the positive electrode portion of the capacitor element is less than a length of the surrounding insulating layer;
wherein the positive side surface of the positive electrode portion of each of the capacitor elements and the at least one negative side surface of the lateral common negative electrode structure that is provided by the negative electrode portions stacked in sequence are not completely covered by the insulating package body;
wherein the positive electrode portion of each of the capacitor elements is configured as a positive conductive pin portion extending horizontally without bending, and the lateral common negative electrode structure that is provided by the negative electrode portions stacked in sequence is configured as a negative conductive common portion without being supported by a conductive carrier substrate;
wherein the lateral common negative electrode structure that is provided by the negative electrode portions stacked in sequence is configured as a thickened conductive adhesive structure or a composite conductive adhesive structure;
wherein, when the lateral common negative electrode structure is configured as the thickened conductive adhesive structure, the lateral common negative electrode structure is formed by sequentially connecting the silver glue layers of the capacitor elements, and the lateral common negative electrode structure gradually is configured to gradually shrink toward the second electrode structure layer;
wherein, when the lateral common negative electrode structure is configured as the composite conductive adhesive structure, the lateral common negative electrode structure includes a negative base portion formed by sequentially connecting the silver glue layers of the capacitor elements and a negative thickening portion disposed on the negative base portion, and the negative thickening portion is configured to gradually shrink toward the second electrode structure layer;
wherein the positive side surface of the positive electrode portion of each of the capacitor elements is completely or partially exposed by the first side portion of the insulating package body, and the at least one negative side surface of the lateral common negative electrode structure that is provided by the negative electrode portions stacked in sequence is completely or partially exposed by the second side portion of the insulating package body;
wherein the positive side surface of the positive electrode portion of each of the capacitor elements is exposed from a first side surface of the first side portion of the insulating package body, so that the first electrode structure layer is configured to directly electrically contact the positive side surface of the positive electrode portion of each of the capacitor elements; and
wherein the at least one negative side surface of the lateral common negative electrode structure that is provided by the negative electrode portions stacked in sequence is exposed from a second side surface of the second side portion of the insulating package body, so that the second electrode structure layer is configured to directly electrically contact the at least one negative side surface of the lateral common negative electrode structure.

10. The method according to claim 7,
wherein a top side of a topmost one of the capacitor elements only contacts the insulating package body, and a bottom side of a bottommost one of the capacitor elements only contacts the insulating package body;
wherein the insulating package body has a top packaging portion located between the top side of the topmost capacitor element and an upper surface of the insulating package body, and the insulating package body has a bottom packaging portion located between the bottom side of the bottommost capacitor element and a lower surface of the insulating package body;
wherein a minimum thickness of the top packaging portion and a minimum thickness of the bottom packaging portion are both less than a maximum thickness of each of the capacitor elements, and a volume occupied by the top packaging portion of the insulating package body and a volume occupied by the bottom packaging portion of the insulating package body are both less than a volume occupied by each of the capacitor elements;
wherein the first electrode structure layer includes a first bottom electrode portion disposed on a first partial bottom surface of the insulating package body, and a first side electrode portion disposed on a first side surface of the insulating package body and electrically connected to the first bottom electrode portion;
wherein the second electrode structure layer includes a second bottom electrode portion disposed on a second partial bottom surface of the insulating package body, and a second side electrode portion disposed on a second side surface of the insulating package body and electrically connected to the second bottom electrode portion;
wherein the positive side surface of the positive electrode portion of each of the capacitor elements is configured as a positive electrode cutting surface, and the at least one negative side surface of the lateral common negative electrode structure that is provided by the negative electrode portions stacked in sequence is configured as a negative electrode processing surface;
wherein the positive side surface of the positive electrode portion of each of the capacitor elements directly contacts the first side electrode portion of the first electrode structure layer and is separate from the first bottom electrode portion of the first electrode structure layer;
wherein the at least one negative side surface of the lateral common negative electrode structure that is provided by sequentially stacking the negative electrode portions directly contacts the second side electrode portion of the second electrode structure layer and is separate from the second bottom electrode portion of the second electrode structure layer; and
wherein the stacked capacitor packaging structure is configured as a chip-type capacitor packaging structure without being bent and without being supported by a conductive carrier substrate.
